(19) United States
(12) Patent Application Publication
(10) Pub. No.: US 2008/0067488 A1
(43) Pub. Date: Mar. 20, 2008

(54) PHASE CHANGE MEMORY DEVICE

(75) Inventor: Tsuyoshi KAWAGOE, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/857,719

(22) Filed: Sep. 19, 2007

(30) Foreign Application Priority Data
Sep. 20, 2006 (JP) 2006-254476

(51) Int. Cl. H01L 45/00

(52) U.S. Cl. 257/3; 438/102; 257/E45.002

(57) ABSTRACT

A phase change memory device comprises an Insulating layer and a phase change layer formed on the insulating layer. The phase change layer has a plurality of linear portions. The linear portions extend in a first direction are spaced from each other in a second direction perpendicular to the first direction. The neighboring ones of the linear portions have ends which open.

### BACKGROUND OF THE INVENTION

This invention relates to a phase change memory device and a method of manufacturing the phase change memory device.

A phase change memory device is disclosed in, for example, US 2005/185444 A1, the document being incorporated herein by reference in its entirety

There is a need for a phase change memory device that has a phase memory change layer which is formed on an insulator layer and which does not easily be peeled off or be removed from the insulating layer during a cleaning process.

### SUMMARY OF THE INVENTION

According to one aspect of the present invention, a phase change memory device comprises an insulating layer and a phase change layer formed on the insulating layer. The phase change layer has a plurality of linear portions each extending In a first direction. The linear portions are spaced from each other in a second direction so that the neighboring ones of the linear portions have ends which are open. At least one of the linear portions has a pad portion which is connected to the end of the linear portion. The pad portion has a point symmetry shape. A center line of the pad portion is in a line with a center line of the linear portion.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a cross-sectional view of a phase change memory device according to a first embodiment of the present invention;

FIG. 2 is a plan view of a phase change layer of the phase change memory device of FIG. 1;

FIG. 3 is a cross-sectional view of the phase change layer of FIG. 2, taken along lines III-III;

FIG. 4 is a cross-sectional view showing a fabrication process for the phase change memory device of FIG. 1;

FIG. 5 is a cross-sectional view showing a subsequent fabrication process for the phase change memory device of FIG. 1;

FIG. 6 is a plan view of a phase change layer according to a second embodiment of the present invention;

FIG. 7 is a cross-sectional view of the phase change layer of FIG. 6, taken along lines VII-VII;

FIG. 8 is a plan view of a phase change layer according to a third embodiment of the present invention;

FIG. 9 is a plan view of a phase change layer according to a fourth embodiment of the present invention;

FIG. 10 is a plan view of a phase change layer according to a modification of the fourth embodiment; and

FIG. 11 is a plan view of a phase change layer according to a fifth embodiment of the present invention.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the Intention is to cover all modifications, equivalents and alternatives falling within the spirit and scope of the present invention as defined by the appended claims.

### DESCRIPTION OF PREFERRED EMBODIMENTS

### First Embodiment

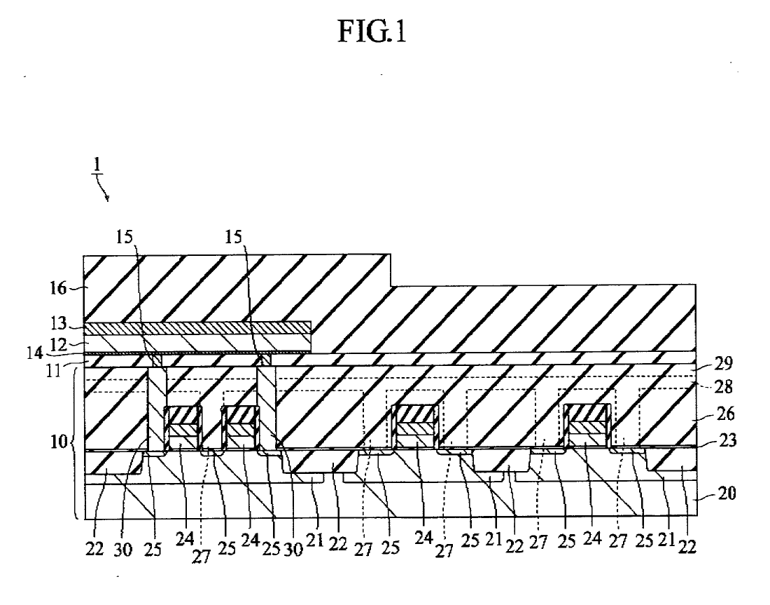

Referring to FIG. 1, a phase change memory device 1 according to a first embodiment of the present invention comprises a lower layer 10, an insulator layer 11, a phase change layer 12, a metal layer 13, an adhesive layer 14, heater electrodes 15, and an upper layer 18.

The lower layer 10 includes a silicon substrate 20, a plurality of Impurity diffusion regions 21, a plurality of isolation regions 22, an insulator film 23, a plurality of gate electrodes 24, a plurality of source/drain regions 25, a first Insulator layer 26, a plurality of first contact plugs 27, a wiring layer 28, a second insulator layer 29, and a plurality of second contact plugs 30.

The impurity diffusion layers 21 are formed in the silicon substrate 20.

The isolation regions 22 are formed in the silicon substrate 20 by forming a plurality of grooves in the silicon substrate 20, followed by filling the grooves with silicon oxide materials (SiO₂). The isolation regions 22 are provided so that the Impurity diffusion regions 21 are isolated from each other by the isolation regions 22 and each of the impurity diffusion regions 21 is divided into a plurality of sections by the isolation region(s) 22.

The insulator film 23 is made of silicon oxide film and is formed on the surface of the silicon substrate 20 as well as on the surfaces of the plurality of the Impurity diffusion layers 21 and the plurality of isolation layers 22.

The gate electrodes 24 are formed on the insulator film 23 at the positions over the impurity diffusion regions 21. Each of the gate electrodes 24 is made of a poly-silicon film (poly-Si) and a tungsten suicide film (WSi) stacked on the poly-silicon film. On the tungsten silicide film, a silicon nitride film (SiN) is formed. The silicon nitride film is used as a hard mask in the process of etching the gate electrodes 24. In addition, each of the gate electrodes 24 Is formed with side walls. The side walls are formed by etchback of other silicon nitride films.

The source/drain regions 25 are formed by doping impurities to the surface of the impurity diffusion regions 21. The source/drain regions 25 are positioned on both sides of each of the gate electrodes 24.

The first insulator layer 26 is formed by depositing a silicon oxide material on the insulator film 23 and the gate electrodes 24, followed by exposing it to a CMP (Chemical Mechanical Polishing) process.

The first contact plugs 27 are formed as follows: first contact holes are formed over the source/drain regions 25 by a photolithography process and a dry etching process, the first contact holes penetrating the first insulator layer 26 and the insulator film 23; the first contact holes are then filled with tungsten material. Finally, the excess amount of tungsten material is removed by a CMP process.

The wiring layer 28 Is formed by patterning tungsten film formed on the first insulator layer 26. The patterning of the tungsten film is carried out through a photolithography process and a dry etching process. The wiring layer 28 includes bit lines connected to the first contact plugs 27 as well as local interconnections of peripheral circuits.

The second insulator layer 29 Is formed by depositing a silicon oxide material on the first insulator layer 26 and on the wiring layer 28, followed by exposing it to a CMP process.

The second contact plugs 30 are formed as follows; second contact holes are formed over the source/drain regions 25 by a photolithography process and a dry etching process, the second contact holes penetrating the first Insulator layer 26, the insulator film 23, and the second insulator layer 29; the second contact holes are then filled with poly-silicon material that Is doped with the impurities. Finally, the excess amount of poly-silicon material is removed by a CMP process.

Description will now be made about the structure of the upper part, specifically above the lower layer 10, of the phase change memory 1 according to the present embodiment.

The insulator layer 11 is made of silicon oxide and is formed on the second insulator layer 29 and the second contact plugs 30.

The heater electrodes 15 are made of tungsten. Each of the heater electrodes 15 is formed on the corresponding one of the second contact plugs 30 and penetrates the insulator layer 11 in the vertical direction.

The adhesive layer 14, the phase change layer 12, and the metal layer 13 are formed on the insulator layer 11 in this order. Herein, the adhesive layer 14 is made of titan. The phase change layer 12 is made of chalcogenide. The metal layer 13 is made of tungsten. The shapes of the adhesive layer 14, the phase change layer 12, and the metal layer 13 are the same except for their thicknesses in the vertical direction. The adhesive layer 14, the phase change layer 12, and the metal layer 13 are formed above and over the second contact plugs 30. During the manufacturing process of the phase change memory device, the adhesive layer 14 may diffuse into the phase change layer 12 when heated. Therefore, there might not be a distinctive boundary to be observed between the phase change layer 12 and the metal layer 13.

The upper layer 16 is made of silicon oxide and is formed over the adhesive layer 14, the phase change layer 12, the metal layer 13, and the insulator layer 11,

The lower layer 10 and the upper layer 16 are provided with various components such as the wiring layer.

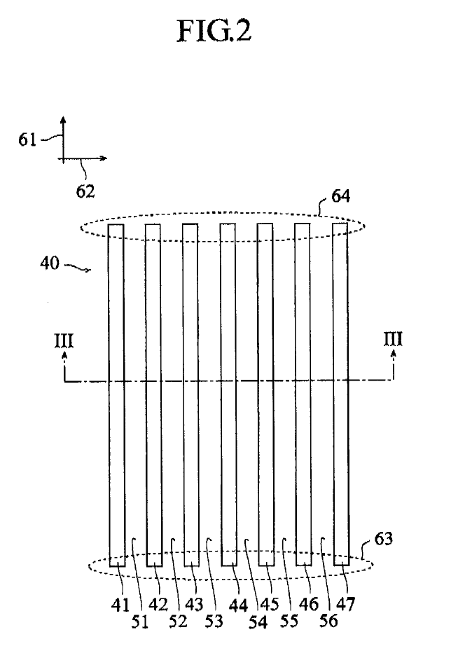

Referring to FIG. 2, the phase change layer 12 includes a group of linear portions 40. The adhesive layer 14 and the metal layer 13 are patterned in the manner same as the group of linear portions 40.

According to the first embodiment, the linear portions 40 includes first to seventh linear portions 41 to 47. Each of the linear portions 41 to 47 has two end portions 63 and 64. The first to the seventh linear portions 41 to 47 extend in a first direction 61 and are spaced from each other in a second direction 62 perpendicular to the first direction 61. Each of the first to the seventh linear portions 41 to 47 has a width of 300 nm in the second direction 62. In this embodiment, the end portions 63, as well as the end portions 64, are arranged in a line in the second direction 62.

According to the first embodiment, the linear portions may function as the phase change memory which store information by the phase-change. Alternatively, the linear portions may constitute a Test Element Group (TEG) for a testing purpose.

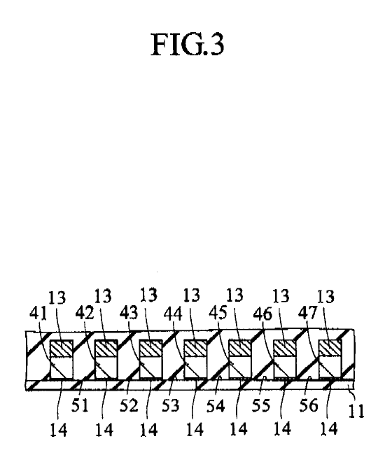

Referring to FIG. 3 together with FIG. 2, the first to the seventh linear portions 41 to 47 are spaced at regular intervals in the second direction 62 by 200 nm. In other words, first to sixth grooves 51 to 56 of 200 nm width are respectively formed between the neighboring ones of the linear portions 41 to 47. The linear portions 41 to 47 are not connected to each other at the end portions 63 and 64. Therefore, the first to the sixth grooves 51 to 56 open at their ends in the first direction 61.

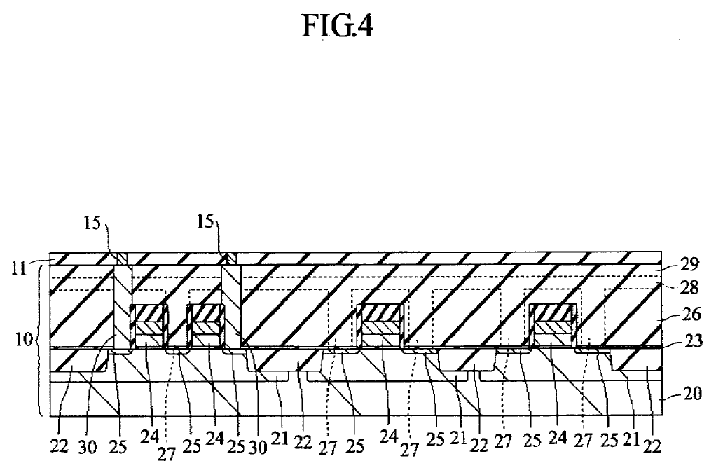

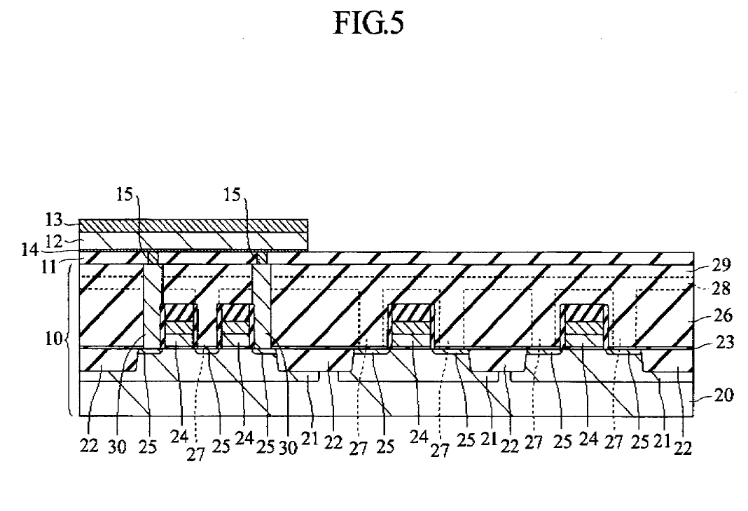

Referring to FIGS. 4 and 5, description will be made about a method of manufacturing a phase change memory 1. The description will be particularly made about the processes to be carried out after the lower layer 10 has been formed.

With reference to FIG. 4, the insulator layer 11 is formed on the lower layer 10 so that the insulator layer 11 covers the second insulator layer 29 and the second contact plugs 30. The Insulator layer 11 according to this embodiment is made of silicon oxide film; however, the insulator layer 11 may be made of other materials such as silicon nitride film.

Next, a plurality of third contact holes are formed in the insulator layer 11 by photolithography and dry etching processes. The formed third contact holes penetrate the insulator layer 11 in the vertical direction to reach the second contact plugs 30.

Next, a titan film is formed in each of the third contact holes so as to form a suicide. Then the titanium nitride (TiN) film is formed in each of the third contact holes as a reaction prevention layer. Thereafter, a tungsten film as a conductive film is formed Inside each of the third contact holes. Herein the holes are completely filled. After the tungsten film is formed, the extra films are removed by a chemical mechanical polishing (CMP) process. The heater electrode 15 is thus formed in each of the third contact holes,

Next, titan material, chalcogenide material, and tungsten material are deposited on the heater electrodes 15 and the insulator layer 11 in this order. Then the titan material, the chalcogenide material, and the tungsten material are subjected to patterning process by means of photolithography and dry etching to be patterned into the pattern as illustrated in FIG. 2. Thus the titan material, the chalcogenide material, and the tungsten material are processed into the adhesive layer 14, the phase change layer 12, and the metal layer 13, respectively, as illustrated in FIG. 5. The adhesive layer 14, the phase change layer 12, and the metal layer 13 may be patterned separately from each other. Subsequently, a hard mask (not shown) made of silicon oxide film is formed on the metal layer 13.

After the hard mask has been formed, a wafer is subjected to a wet cleaning process. During a wet cleaning process, the wafer is cleaned in a single wafer cleaning equipment by the use of a cleaning liquid such as pure water or a chemical solution. According to the first embodiment, the cleaning liquid flows in the first direction 61.

As shown in FIG. 2, the end portions 63 and 64 are open. Therefore, the cleaning liquid can be introduced to and discharged from the group of linear portions 40 without being blocked. With this structure, the patterned phase change layer 12 will not easily be peeled off or removed by the flow of the cleaning liquid.

As shown in FIG. 1, after the cleaning process, the hard mask (not shown) on the metal layer 13 is removed therefrom, and the upper layer 16 made of silicon oxide film Is formed on the adhesive layer 14, the phase change layer 12, and the metal layer 13.

### Second Embodiment

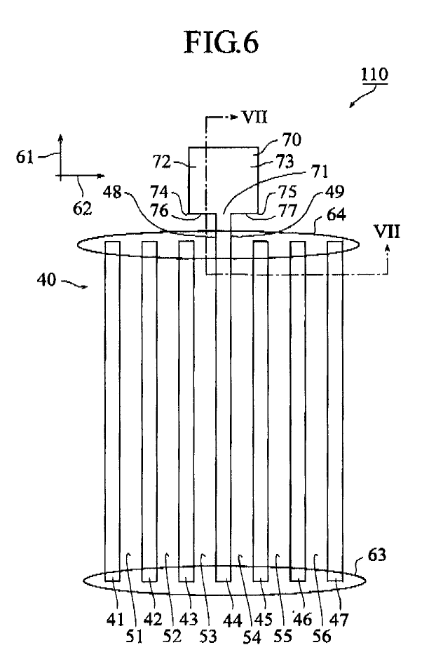

Referring to FIG. 6, the phase change layer 12 according to a second embodiment of the present invention has a structure same as the first embodiment except for that the phase change layer 12 is provided with a pad portion 70.

According to the second embodiment, the fourth linear portion 44 has a length slightly longer, by 0.5 μm to 5 μm in this embodiment, than others so that the end portion 64 of the fourth linear portion 44 sticks out from the line on which the end portions 64 of the other linear portions 41-43, 45-47 are arranged. The width of the linear portion 44 in the second direction 62 is defined by side surfaces 48 and 49. According to the second embodiment, the side surfaces 48 and 49 are provided along the first direction 61 of the linear portion 44.

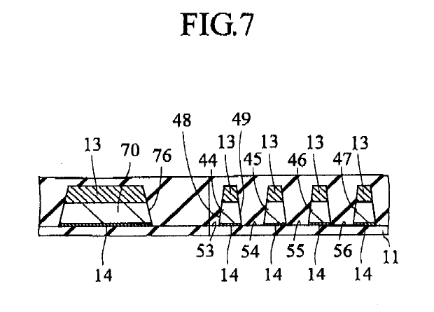

Referring to FIG. 7, the first to the seventh linear portions 41 to 47 may have the width in the second direction 62 which is larger at the bottom, i.e., at the portion near the adhesive layer 14 and smaller at the top, i.e., at the portion near the metal layer 13. In other words, the side surfaces of the linear portions 41 to 47 may be inclined with respect to the insulator layer 11. Accordingly, the side surfaces of the adhesive layer 14 and the metal layer 13 may also be inclined with respect to the Insulator layer 11 so that the side surfaces of the adhesive layer 14, the phase memory layer 12, and the metal layer 13 may form a uniform surface and may be integrally inclined with respect to the insulator layer 11.

Referring back to FIG. 6, the pad portion 70 is connected to the end portion 64 of the fourth linear portion 44 at a connecting portion 71. In this embodiment, the pad portion 70 has a square shape whose edges extend in the first direction 61 or the second direction 62. The pad portion 70 has a first imaginary center line extending in the first direction 61. The fourth linear portion 44 has a second imaginary center line extending in the first direction 61. The pad portion 70 is connected to the linear portion 44 so that the first imaginary center line is in a line with the second imaginary center line.

As shown in FIG. 7, the pad portion 70 may have the side surfaces which are inclined with respect to the insulator layer 11 in the manner similar to the linear portions 41 to 47. In other words, the pad portion 70 may have the width which is larger at the bottom, i.e., near the insulator layer 11 and smaller at the top, i.e., near the metal layer 13.

The pad portion 70 has a width that is larger than the linear portions 41 to 47 in the second direction 62. The pad portion 70 is used as a contact portion between the linear portion 44 and another component such as a wiring layer. However, the pad portion 70 may have various other shapes and functions. For example, the pad portion 70 may be a separated or an isolated portion to establish the electrical connections between the wiring layers.

The pad portion 70 is divided into two parts, namely, a first region 72 and a second region 73 by the first imaginary center line. In other words, the first region 72 and the second region 73 are in the symmetrical shape. The first region 72 has a corner 74 and a side portion 76 for connecting the corner 74 with the side surface 48. Similarly, the second region 73 has a corner 75 and a side portion 77 for connecting the corner 75 with the side surface 49. The side portion 76 and the side portion 77 have the equal length. Therefore, during the cleaning process, the pressure due to the flow of the cleaning liquid is equally applied to both side portions 76 and 77. With this structure, the phase change layer 12 may not be easily peeled off from the Insulator layer 11.

### Third Embodiment

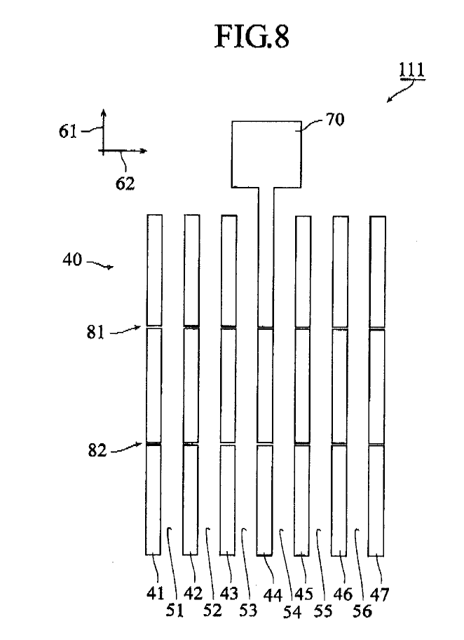

Referring to FIG. 8, the phase change layer 111 according to the third embodiment of the present invention has the structure similar to the second embodiment except for that a plurality of first slits 81 and a plurality of second slits 82 are provided to the group of the linear portions 40. Specifically, according to the third embodiment, each of the linear portions 41 to 47 is provided with the first slit 81 and the second slit 82, both extending in the second direction 62. Each of the linear portions 41 to 47 are equally divided Into three by the slit 81 and the slit 82.

With this structure, the cleaning liquid flows in the first direction 61 and also in the second direction 62 during the cleaning process. Therefore, as the flow of the cleaning liquid is distributed in two directions, the pressure due to the flow to the side portions 76 and 77 can be reduced.

Preferably, the slits 81 and 82 are provided to all the linear portions. However, the slits 81 and 82 may be provided to specific ones of the linear portions. Moreover, the slits 81 are preferably aligned in a line. Likewise, the slits 82 are preferably aligned in a line. However, the slits 81 and 82 may be arranged In a different pattern.

In the third embodiment, it is preferable that each of the linear portions 41 to 47 be divided by the slits 81 and 82 so that each of the divided portions has the length substantially equal to or more than 200 μm.

### Fourth Embodiment

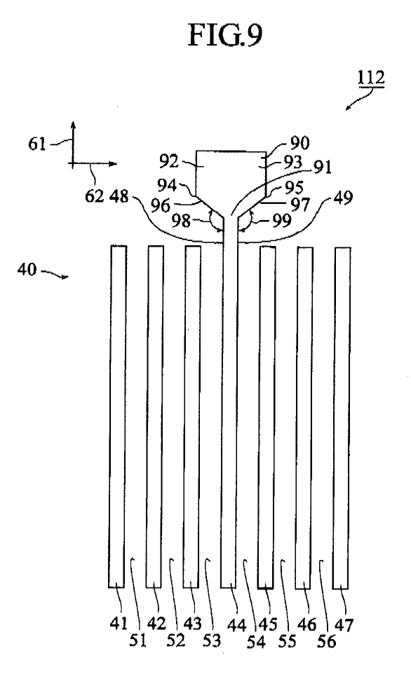

Referring to FIG. 9, the phase change layer 112 according to a fourth embodiment of the present Invention has the structure similar to the second embodiment except for that a shape of a pad portion 90 is different.

According to the fourth embodiment, the pad portion 90 has a home plate shape and is connected to the fourth linear portion 44 at a connecting portion 91. The pad portion 90 is divided into two parts, namely, a first region 92 and a second region 93 by the first imaginary center line. In other words, the first region 92 and the second region 93 are in the symmetrical shape.

The first region 92 has an obtuse corner 94 and a side portion 96 for connecting the corner 94 with the side surface 48. Similarly, the second region 93 has an obtuse corner 95 and a side portion 97 for connecting the corner 95 with the side surface 49. The side portion 96 and the side portion 97 have the equal length.

An angle 98 between the side surface 48 and the end portion 94 forms an obtuse angle. Similarly, an angle 99 between the side surface 49 and the end portion 97 forms an obtuse angle. The angles 98 and 99 are equal in degree. Therefore, the pressure due to the flow of the cleaning liquid during the cleaning process is equally applied to both side portions 96 and 97. Also, the pressure applied to the side portions 96 and 97 can be reduced because the cleaning liquid smoothly flows along the Inclined side portions 96, 97 of the pad portion 90. With this structure, the phase change layer 12 may not easily be peeled off from the insulator layer 11.

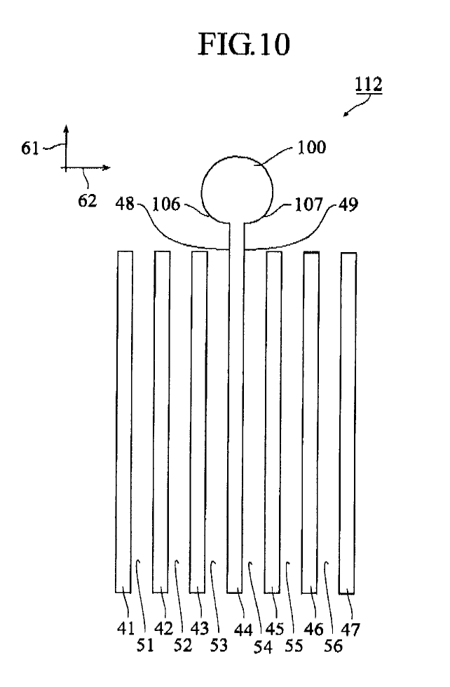

As shown in FIG. 10, the phase change layer 112 may be modified so that a pad portion 100 has a round shape. The flow of the cleaning liquid is received by side portions 106 and 107 and is guided along the circumference of the pad portion 100. With this structure, the pressure due to the flow of the cleaning liquid to the pad portion 100 may be reduced.

### Fifth Embodiment

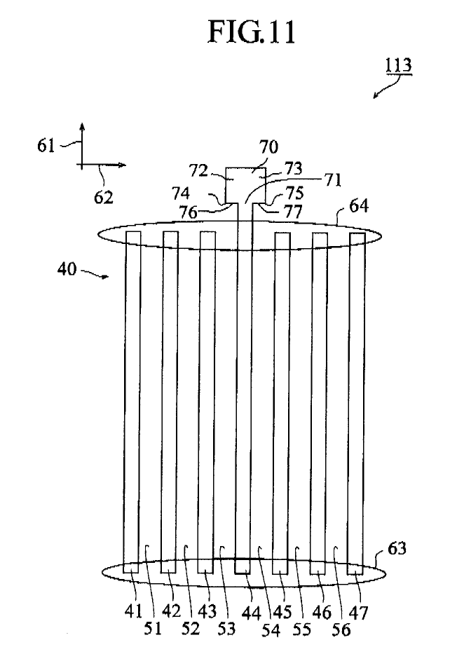

Referring to FIG. 11, the phase change layer 113 according to a fifth embodiment of the present invention has the structure similar to the second embodiment except for that the size of the pad portion 70a is different.

The pad portion 70a Is divided into two parts, namely, a first region 72a and a second region 73a by an imaginary center line. In other words, the first region 72a and the second region 73a are in the symmetrical shape. The first region 72a has a corner 74a and a side portion 76a for connecting the corner 74a with the side surface 48. Similarly, the second region 73a has a corner 75a and a side portion 77a for connecting the corner 75a with the side surface 49.

The length of the side portion 76a is shorter than the width of the third groove 53 in the second direction 62. Similarly, the length of the side portion 77a is shorter than the width of the fourth groove 54 in the second direction 02. The side portions 76a and 77a have equal length.

With this structure, during the cleaning process, there are formed larger passages for the cleaning liquids flowing through the grooves 53 and 54, in comparison with the first embodiment. Therefore, the pressure due to the flow of the cleaning liquid to the side portions 76a and 77a may be more reduced.

In the above-described embodiments, the number of linear portions are seven but may be two or more other than seven.

The phase change layer may be used for memory cells, for the TEG, or may be arranged in a periphery circuit regions in the vicinity of the memory cells.

The present application is based on Japanese patent applications of JP2006-254476 filed before the Japan Patent Office on Sep. 20, 2006, the contents of which are incorporated herein by reference.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. A phase change memory device comprising an insulating layer and a phase change layer formed on the insulating layer, the phase change layer having a plurality of linear portions each extending in a first direction, the linear portions being spaced from each other in a second direction perpendicular to the first direction so that the neighboring ones of the linear portions have ends which open.

2. The phase change memory device as claimed in claim 1, wherein the linear portions are arranged in parallel with each other.

3. The phase change memory device as claimed in claim 1, wherein the linear portions are spaced at regular intervals in the second direction.

4. The phase change memory device as claimed in claim 1, wherein each of the linear portions is provided with at least one slit extending in the second direction.

5. The phase change memory device as claimed in claim 1, wherein at least one of the linear portions has a pad portion, the pad portion being connected to the and of the linear portion.

6. The phase change memory device as claimed in claim 1, wherein the pad portion has a specific shape with a first imaginary center line extending in the first direction, the specific shape being a symmetrical shape with respect to the first imaginary center line, each of the linear portions having a second imaginary center line extending in the first direction, the pad portion being connected to one of the linear portions so that the first imaginary line is in a line with the second imaginary center line.

7. The phase change memory device as claimed in claim 5, wherein the specific shape being a rectangular shape.

8. The phase change memory device as claimed in claim 5, wherein the specific shape being a home plate shape.

9. The phase change memory device as claimed in claim 5, wherein the specific shape being a round shape.

10. A method of manufacturing a phase change memory device, the method comprising:
forming a phase change layer on the Insulator layer;
patterning the phase change layer so that a plurality of linear portions are formed on the insulator layer, the linear portions extending in a first direction and being spaced from each other in a second direction perpendicular to the first direction so that the neighboring ones of the linear portions have ends which open; and
cleaning the patterned phase change layer.
